(19) United States
(12) Patent Application Publication
(10) Pub. No.: US 2024/0304678 A1
(43) Pub. Date: Sep. 12, 2024

(54) METHODS OF FORMING HIGH ELECTRON MOBILITY TRANSISTORS WITH CONTROLLED GATE LENGTH AND HIGH ELECTRON MOBILITY TRANSISTORS WITH CONTROLLED GATE LENGTH

(71) Applicant: Woflspeed, Inc., Durham, NC (US)

(72) Inventor: Won Sang Lee, Chapel Hill, NC (US)

(21) Appl. No.: 18/119,795

(22) Filed: Mar. 9, 2023

(51) Int. Cl. H01L 29/40; H01L 21/285; H01L 21/8252; H01L 27/095; H01L 29/20; H01L 29/423; H01L 29/66; H01L 29/778

(52) U.S. Cl. CPC H01L 29/401; H01L 21/28581; H01L 21/8252; H01L 27/095; H01L 29/2003; H01L 29/402; H01L 29/42316; H01L 29/66462; H01L 29/7786

(57) ABSTRACT

A method of forming a transistor device includes providing an epi wafer including a substrate and one or more epitaxial layers, forming source and drain contacts on a surface of the epi wafer, and forming a surface dielectric layer on the surface of the epi wafer. A first opening is formed in the surface dielectric layer. The opening has a first width and exposes a first region of the surface of the epi wafer. A mask layer is formed on the epi wafer. The mask layer has a second opening that is offset from the first opening. The second opening exposes a portion of the first region of the surface of the epi wafer and a portion of the surface dielectric layer adjacent the first region of the surface of the epi wafer. A gate contact is formed in the second opening.

### TECHNICAL FIELD

The present disclosure relates to a semiconductor devices, and in particular to high electron mobility transistor devices.

### BACKGROUND

Semiconductor devices, such as high electron mobility transistors (HEMTs), Schottky diodes, metal semiconductor field effect transistors (MESFETS) and the like employ a non-ohmic contacts to semiconductor layers. A contact that forms a Schottky barrier junction, referred to as a Schottky contact, is an example of a non-ohmic contact. Schottky contacts are generally metal contacts that are formed on a semiconductor material to create a metal-semiconductor junction that tends to provide a rectifying effect due to an inherent potential barrier that is formed at the metal-semiconductor junction. That is, current can flow through a Schottky junction when the junction is forward biased by applying a positive voltage from the metal to the semiconductor. Under reverse bias conditions in which a negative voltage is applied from the metal to the semiconductor, the Schottky junction blocks current flow except for a small leakage current.

A simplified cross-section of an exemplary high electron mobility transistor (HEMT) 100 is shown in FIG. 1A. The HEMT 100 is formed in a semiconductor epitaxial wafer (epiwafer) 115 comprising a Group III nitride material epitaxial layer structure 116, 118 on a substrate 102. In particular, the HEMT 100 is formed in an aluminum gallium nitride (AlGaN)/gallium nitride (GaN) material system, and the substrate 102 is formed of silicon carbide (SiC). The substrate 102 is a semi-insulating substrate formed of a 4H polytype of SiC. Optional SiC polytypes include 3C, 6H, and 15R polytypes. Alternative materials for the substrate 102 may include sapphire (Al₂O₃), aluminum nitride (AlN), AlGaN, GaN, silicon (Si), gallium arsenide (GaAs), zinc oxide (ZnO), and indium phosphide (InP). The substrate 102 is generally between 300 micrometers and 500 micrometers thick.

A nucleation layer may be formed on a surface of the substrate 102 to provide an appropriate crystal structure transition between the SiC of the substrate 102 and the various epitaxial layers that are to be formed on the substrate 102. The nucleation layer may be a single layer or a series of layers. The nucleation layer is generally between 30 nm and 50 nm thick.

A channel layer 116 is formed on the nucleation layer. The channel layer 116 is formed by one or more epitaxial layers. For this example, the channel layer 116 may be GaN. However, the channel layer 116 may more generally be a Group III nitride such as GaN, AlXGa1−XN where 0≤X<1, indium gallium nitride (InGaN), aluminum indium gallium nitride (AlInGaN), or the like. The channel layer 116 may be undoped, or at least unintentionally doped, and may be grown to a thickness of greater than about 2 nm. In certain embodiments, the channel layer 116 may employ a multi-layer structure, such as a superlattice or alternating layers of different Group III-nitrides, such as GaN, AlGaN, or the like.

A barrier layer 118 is formed on the channel layer 116. The barrier layer 118 may have a bandgap that is greater than the bandgap of the underlying channel layer 116. Further, the barrier layer 118 may have a smaller electron affinity than the channel layer 116. In this illustrated embodiment, the barrier layer 118 is AlGaN. However, the barrier layer 118 may include AlGaN, AlInGaN, AlN, or various combinations of these layers. The barrier layer 118 is generally between 2 nm and 40 nm thick; however, the barrier layer 118 should not be so thick as to cause cracking or substantial defect formation therein. The barrier layer 118 may be either undoped, or at least unintentionally doped, or doped with an n-type dopant to a concentration less than about 1E19 cm⁻³. Notably, together, the channel layer 116 and the barrier layer 118 form a semiconductor body of the HEMT 100.

As shown in FIG. 1, a surface dielectric layer 126 is formed on a surface of the barrier layer 118 opposite the channel layer 116 and is etched using known etching techniques to the shape shown. In this embodiment, the surface dielectric layer 126 is silicon nitride (SiN). However, the surface dielectric layer 126 may be formed of another suitable dielectric such as, for example, silicon dioxide (SiO₂), aluminum silicon nitride (AlSiN), silicon oxynitride (SiON), or the like. It will be understood that the terms “SixNy,” “SiN,” and “silicon nitride” are used herein interchangeably to refer to both stoichiometric and non-stoichiometric SiN. Other materials that may be used for the surface dielectric layer 126 include, for example, magnesium oxide, scandium oxide, aluminum oxide, and/or aluminum oxynitride. Furthermore, the surface dielectric layer 126 may be a single layer or may include multiple layers of uniform or non-uniform composition. The material of the surface dielectric layer 126 should be capable of withstanding relatively high temperatures, and should allow at least a portion to be removed without significantly damaging the underlying barrier layer 118.

In general, the surface dielectric layer 126 may provide a relatively high breakdown field strength and a relatively low interface trap density at the interface with an underlying Group III nitride layer such as the barrier layer 118. The surface dielectric layer 126 may have a high etch selectivity with respect to the material of the barrier layer 118, and may not be reactive to the material of the barrier layer 118. Moreover, the surface dielectric layer 126 may have a relatively low level of impurities therein. For example, the surface dielectric layer 126 may have a relatively low level of hydrogen and other impurities, including oxygen, carbon, fluorine, and chlorine. The surface dielectric layer 126 is generally between 80 nm and 200 nm thick.

As illustrated, the surface dielectric layer 126 is etched to expose surface portions 122A, 122B, 122C of the barrier layer 118. The area beneath the surface portion 122A corresponds to the drain region, and the area beneath the surface portion 122B corresponds to the source region. The areas beneath the surface portions 122A and 122B, which correspond to the drain and source regions, are subjected to a “shallow implant” of dopant ions to form respective shallow implant regions 124. The shallow implant regions 124 extend through the barrier layer 118 and at least partially into the channel layer 116. As such, the ions for the doping material come to rest in both the barrier layer 118 and at least the upper portion of the channel layer 116 beneath the surface portions 122A and 122B.

As used herein, the term “shallow implant” means that the implants are made directly into the barrier layer 118 with no substantive capping or protection layer over the surface portions 122A and 122B of the barrier layer 118 during implantation. The implanted ions of the doping material may be implanted such that a peak of the implant profile is located just below the interface between the channel layer 116 and the barrier layer 118 where a two-dimensional electron gas (2-DEG) plane is formed during operation and in which electron conductivity is modulated. While the doping concentrations may vary based on desired performance parameters, first exemplary doping conditions may provide shallow implant regions 124 with a peak doping concentration of 1×10¹⁸ cm⁻³ or greater and a straggle of 50 nanometers (nm) or less. For example, in some embodiments, the dose and energy of the implants may be selected to provide a peak doping concentration of about 5×10¹⁹ cm⁻³ and a straggle of about 30 nm. In order to form n-type shallow implant regions 124 in a nitride-based barrier layer 118, the implanted ions may include Si ions, sulfur ions, oxygen ions, or a combination thereof.

On the surface portion 122A, a drain contact 116 is formed. The drain contact 116 is an ohmic contact that cooperates with the shallow implant region 124 residing beneath the surface portion 122A to provide a low resistance connection to the drain region of the HEMT 100. Similarly, on the surface portion 122B, a source contact 110 is formed. The source contact 110 is an ohmic contact that cooperates with the shallow implant region 124 residing beneath the surface portion 122B to provide a low resistance connection to the source region of the HEMT 100. The source and drain regions connect with the opposite sides of the 2-DEG plane, which is just below the junction of the channel layer 116 and barrier layer 118.

As noted above, the surface dielectric layer 126 is also etched to expose the surface portion 122C of the barrier layer 118. The surface portion 122C resides between the surface portions 122A and 122B and corresponds to a gate region of the HEMT 100. A gate contact 112 is formed with one or more metallic layers over the surface portion 122C of the barrier layer 118. In a depletion mode (D-mode) HEMT device, the gate contact 112 is formed directly on the barrier layer 118 as illustrated. In contrast, in an enhancement mode (E-mode) HEMT device, an insulation layer may be provided between the gate contact 112 and the barrier layer, as discussed in more detail below. Charge in the insulation layer may deplete the 2DEG of carriers under zero gate bias conditions. Thus, an enhancement mode device may be normally OFF (i.e., non-conducting) until a bias voltage is applied to the gate contact 112.

Referring still to FIG. 1A, a portion of the gate contact 112 may be formed directly on the barrier layer 118, which itself may be formed from multiple epitaxial layers. Typically, an opening is etched through the surface dielectric layer 126 to expose the surface portion 122C. As illustrated, the gate contact 112 may have a portion that resides within the opening in contact with the surface portion 122C as well as portions that reside along the sidewalls of the opening and on an upper surface of the surface dielectric layer 126 on either side of the opening.

The gate contact 112 forms a non-ohmic contact with the barrier layer 118, and in particular may form a Schottky contact to the barrier layer 118.

A second dielectric layer 128 is formed over the surface dielectric layer 126 and the gate contact 112. A drain metallization layer 132 contacts the drain contact 116 through the second dielectric layer 128, and a source metallization layer 134 contacts the source contact 110 through the second dielectric layer 128. A field plate 122 is electrically connected to the source contact 110 via the source metallization layer 134 and extends over the gate contact 112. The field plate 122 reduces the negative impact of nearby electromagnetic fields on the gate contact 112 of the HEMT 100. The source metallization 134 connects to a backside source electrode 123 via a backside via 118 through the epiwafer 115.

Under normal conditions, a channel is formed from the source contact 110 to the drain contact 116 through a channel that is formed by the 2DEG at the interface of the channel layer 116 and the barrier layer 118. In a D-mode device, to pinch off the channel and switch the device off, a negative voltage is applied to the gate contact 112, which depletes the 2DEG of carriers in a region beneath the gate contact 112.

A conventional process for forming the gate contact of a HEMT device 100 is illustrated in FIGS. 1B to 1E. Referring to FIG. 1B, a source contact 110 and drain contact 116 are formed on a semiconductor epiwafer 115. A surface dielectric layer 126 is formed on the surface of the epiwafer 115 over the source 110 and drain 116 contacts. An opening 126A is formed in the surface dielectric layer 126 using conventional lithographic techniques to expose a surface portion 122C of the epiwafer 115.

Referring to FIG. 1C, a mask layer 111 is formed on the structure, and an opening 111A is formed in the mask layer above the opening 126A in the surface dielectric layer 126 and the exposed surface portion 122C of the epiwafer 115. The opening 111A in the mask layer 111 is wider than the opening 126A in the surface dielectric layer 126, so that portions of the surface dielectric layer 126 are exposed within the opening 111A.

Referring to FIG. 1D, a gate metallization 112A is deposited in the opening 111A to form a gate contact 112. Portions of the gate contact 112 outside the opening 126A extend onto the surface dielectric layer 126 to form a T-gate arrangement.

Referring to FIG. 1E, the mask layer 111 is then removed, leaving the gate contact 112 that contacts the epiwafer 115 in the region 122C and that extends onto the surface dielectric layer 126 in a T-gate arrangement. The gate contact 112 has a gate length Lg that is defined by the width of the portion of the gate contact 112 that is in contact with the epiwafer 115 in the region 122C.

### SUMMARY

A method of forming a transistor device according to some embodiments includes providing an epi wafer including a substrate and one or more epitaxial layers, forming source and drain contacts on a surface of the epiwafer, and forming a surface dielectric layer on the surface of the epiwafer. As used herein, the term “epi wafer” refers to a semiconductor substrate on which one or more epitaxial semiconductor layers are formed. A first opening is formed in the surface dielectric layer. The opening has a first width and exposes a first region of the surface of the epiwafer. A mask layer is formed on the epiwafer. The mask layer has a second opening that is offset from the first opening, wherein the second opening exposes a portion of the first region of the surface of the epiwafer and a portion of the surface dielectric layer adjacent the first region of the surface of the epiwafer. The method further includes forming a gate contact in the second opening.

The portion of the first region of the surface of the epiwafer that is exposed by the second opening may have a second width that is smaller than a first width of the first opening in the surface dielectric layer.

The second width may be less than about 0.1 microns. In some embodiments, the second width is between about 0.05 microns and 0.08 microns. In some embodiments, the second width is about 0.07 microns.

The mask layer may extends into the first opening in the surface dielectric layer, and the method may further removing the mask layer, wherein removing the mask layer exposes a portion of the first region of the surface of the epi wafer that was covered by the mask layer.

The gate contact may extend across the portion of the surface dielectric layer adjacent the first region of the surface of the epi wafer.

The portion of the surface dielectric layer adjacent the first region of the surface of the epi wafer may be between the first region of the surface of the epi wafer and the drain contact.

The method may further include, after forming the gate contact, forming an insulation layer on the epi wafer, wherein the insulation layer covers the gate contact and the surface dielectric layer. The insulation layer may have a different material composition than the surface dielectric layer. In some embodiments, the surface dielectric layer includes silicon nitride, and the insulation layer includes aluminum oxide. The insulation layer may have a thickness of about 10 nanometers.

The method may further include, before forming the gate contact, forming an insulation layer on the epi wafer, wherein the insulation layer covers the surface dielectric layer and the first region of the surface of the epiwafer. Forming the gate contact includes forming the gate contact on the insulation layer.

The epi wafer may include an epitaxial structure including a channel layer and a barrier layer that are configured to form a two-dimensional electron gas (2DEG) at an interface between the channel layer and the barrier layer. A material composition and thickness of the insulation layer may be selected to deplete the 2DEG of carriers under zero bias conditions.

A semiconductor transistor device according to some embodiments includes a substrate and a semiconductor epitaxial structure on the substrate, a source contact on a surface of the semiconductor epitaxial structure, a drain contact on the surface of the semiconductor epitaxial structure, and a gate contact on the surface of the semiconductor epitaxial structure between the source contact and the drain contact. The gate contact has a gate length less than about 0.1 microns.

The gate length may be between about 0.05 microns and 0.08 microns. In some embodiments, the gate length is about 0.07 microns. In some embodiments, the gate contact has a gamma-gate arrangement.

The semiconductor transistor device may be configured to operate at frequencies greater than 1 GHz.

The semiconductor transistor device may further include an insulation layer on the surface of the semiconductor epiwafer between the gate contact and the semiconductor epiwafer.

The semiconductor epitaxial structure may include a channel layer and a barrier layer that are configured to form a two-dimensional electron gas (2DEG) at an interface between the channel layer and the barrier layer. A material composition and thickness of the insulation layer may be selected to deplete the 2DEG of carriers under zero bias conditions.

The insulation layer may include aluminum oxide and have a thickness of at least about 10 nanometers.

Some embodiments provide a monolithic microwave integrated circuit (MMIC) including a semiconductor transistor device having a substrate and a semiconductor epitaxial structure on the substrate, a source contact on a surface of the semiconductor epitaxial structure, a drain contact on the surface of the semiconductor epitaxial structure, and a gate contact on the surface of the semiconductor epitaxial structure between the source contact and the drain contact.

A method of forming a transistor device according to some embodiments includes providing an epiwafer including a substrate and one or more epitaxial layers, forming first source and drain contacts on a surface of the epiwafer, forming second source and drain contacts on the surface of the epiwafer, and forming a surface dielectric layer on the surface of the epiwafer. A first opening is formed in the surface dielectric layer between the first source and drain contacts. The first opening has a first width and exposing a first region of the surface of the epiwafer.

A second opening is formed in the surface dielectric layer between the second source and drain contacts. The second opening has a second width and exposing a second region of the surface of the epiwafer.

A first gate contact is formed in the first opening. The first gate contact has a first gate width that is less than the first width.

An insulation layer is formed on the surface of the epiwafer. The insulation layer covers the surface dielectric layer, the first and second source and drain contacts, the first gate contact, and the second opening.

A second gate contact is formed in the second opening. The second gate contact has a second gate width that is less than the second width.

Forming the first opening and the second opening may include forming a mask layer on the epi wafer, the mask layer having a third opening that is offset from the first opening. The third opening exposes a portion of the first region of the surface of the epi wafer and a portion of the surface dielectric layer adjacent the first region of the surface of the epi wafer and having a fourth opening that is offset from the second opening. The fourth opening exposes a portion of the second region of the surface of the epi wafer and a portion of the surface dielectric layer adjacent the second region of the surface of the epi wafer.

The insulation layer may have a different material composition than the surface dielectric layer. In some embodiments, the surface dielectric layer includes silicon nitride, and the insulation layer includes aluminum oxide.

The epi wafer may include an epitaxial structure including a channel layer and a barrier layer that are configured to form a two-dimensional electron gas (2DEG) at an interface between the channel layer and the barrier layer. A material composition and thickness of the insulation layer are selected to deplete the 2DEG of carriers under zero bias conditions in an area beneath the second gate contact.

An integrated electronic device according to some embodiments includes a semiconductor die including a substrate and an epitaxial structure on the substrate, a depletion mode high electron mobility transistor (HEMT) device in a first region of the semiconductor die, and an enhancement mode HEMT device in a second region of the of the semiconductor die. The depletion mode HEMT includes first source and drain contacts, a first gate contact between the first source and drain contacts, and an insulation layer above the first gate contact, wherein the first gate contact directly contacts the epiwafer. The enhancement mode HEMT includes second source and drain contacts and a second gate contact between the second source and drain contacts, wherein the insulation layer is between the second gate contact and the epiwafer.

### BRIEF DESCRIPTION OF THE DRAWINGS

FIG. 1A is a simplified cross-section of a conventional high electron mobility transistor.

FIGS. 1B to 1E illustrate operations for forming a conventional HEMT device structure.

FIGS. 2A to 2H illustrate operations for forming a HEMT device structure according to some embodiments.

FIGS. 3A to 3H illustrate operations for forming a HEMT device structure according to further embodiments.

FIGS. 4A to 4J illustrate operations for forming a HEMT device structure according to further embodiments.

FIG. 5 illustrates a HEMT structure according to some embodiments.

FIG. 6 illustrates a HEMT structure according to some embodiments.

FIGS. 7A to 7J illustrate operations for forming HEMT device structures according to further embodiments.

FIGS. 8A to 8J illustrate operations for forming HEMT device structures according to further embodiments.

FIGS. 9A-9C are schematic block diagrams of multi-amplifier circuits in which RF power amplifiers incorporating transistor devices according to embodiments may be used.

FIG. 10 is a schematic plan view of a monolithic microwave integrated circuit RF power amplifier according to some embodiments.

FIGS. 11A and 11B are schematic cross-sectional views illustrating two example ways that an RF transistor device according to some embodiments may be packaged to provide RF power amplifiers.

### DETAILED DESCRIPTION OF EMBODIMENTS

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

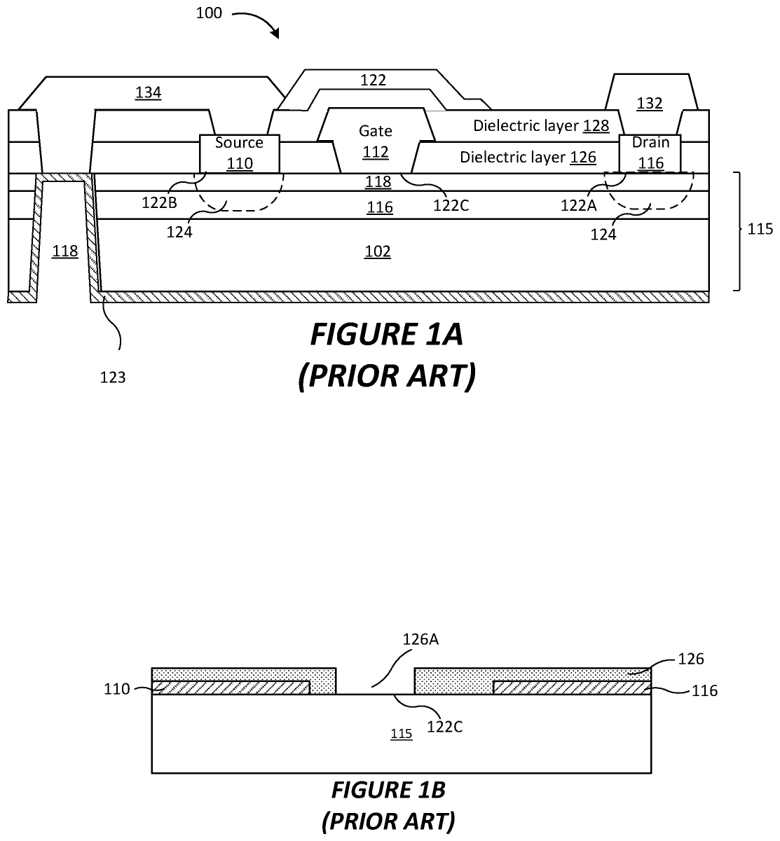

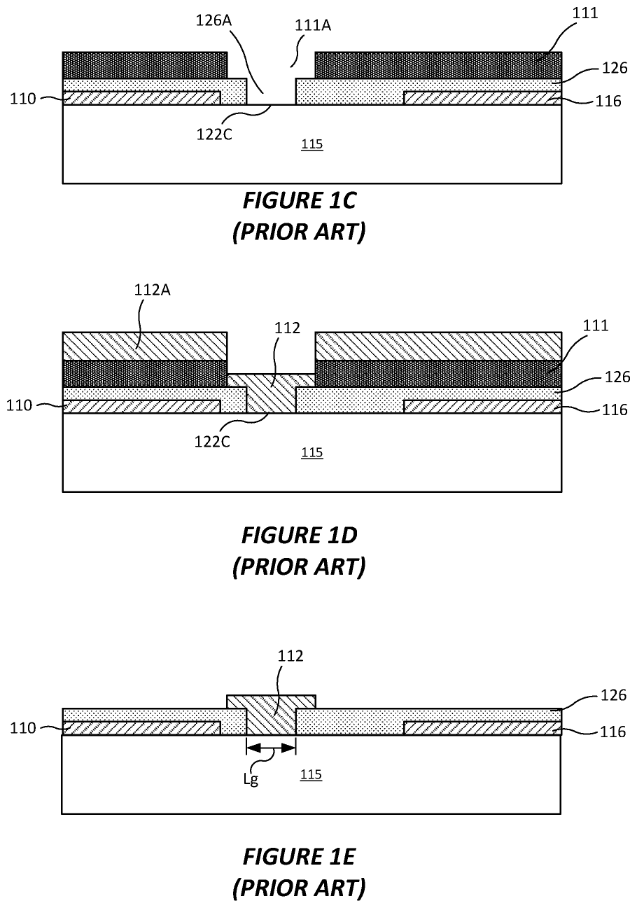

One problem with the conventional process for forming a gate contact of a HEMT device as illustrated in FIGS. 1B to 1E is that it is difficult to reduce the gate length using conventional photolithographic techniques. In particular, it may be difficult to form a gate contact having a gate length of less than 0.1 microns due to the resolution limits of optical lithography. Some embodiments provide methods of forming a gate contact for a HEMT device using an offset lithography technique to form a gamma-gate device having a shorter gate length that may be obtained using conventional techniques. Moreover, some embodiments provide methods of forming a HEMT device that enables formation of both E-mode and D-mode devices on a single epiwafer.

Forming a transistor device with a reduced gate length of a gamma gate according to some embodiments may have a number of beneficial effects on the operation of the device. For example, it may improve the cut-off frequency of the device. Moreover, the operating drain voltage of the device may be increases up to 40V. The RF output power of the device may be improved, along with improving the characteristics of short channel effect in the device. Additionally, the breakdown voltage of the device may be improved.

Devices formed according to some embodiments described herein may be applicable as RF devices for Ka-band and V-band, power transistors, power amplifier monolithic microwave integrated circuits (MMICs), low noise amplifier MMICs, single pole dual throw (SPDT) switch MMICs, one chip solutions for front end modules (e.g., including power amplifier, low noise amplifier and switch, as optical communication switches, and/or direct coupled field effect transistor (FET) logic.

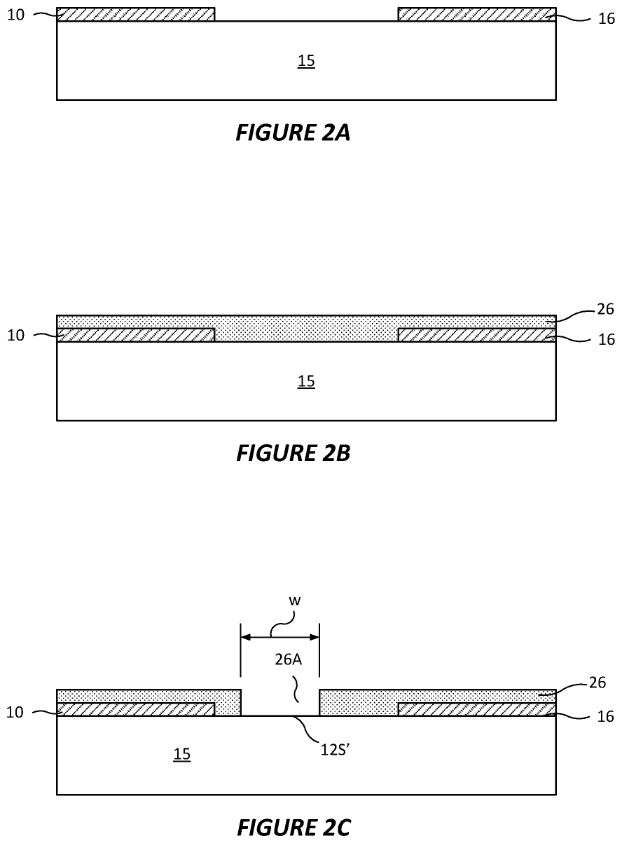

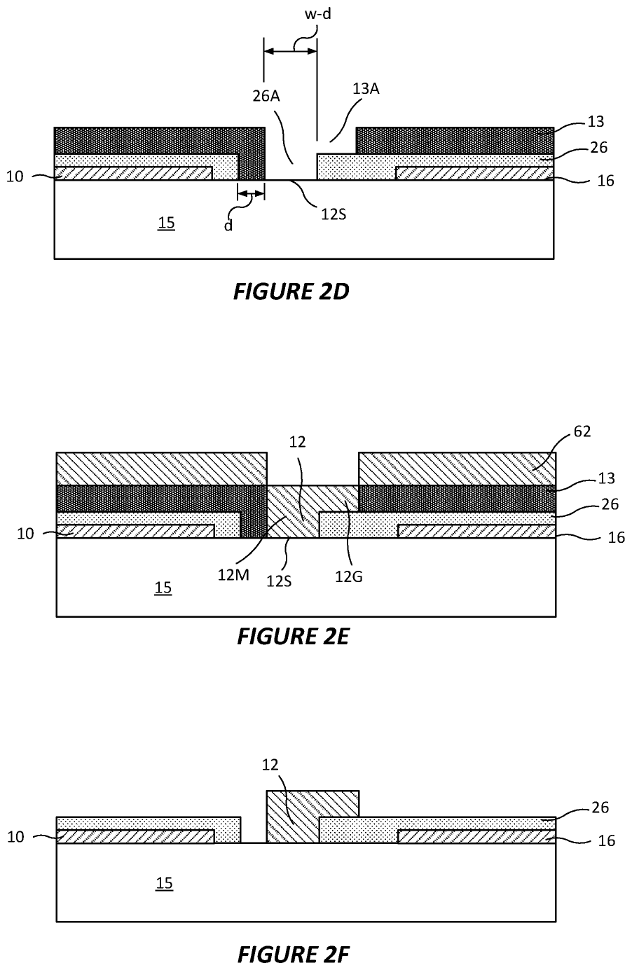

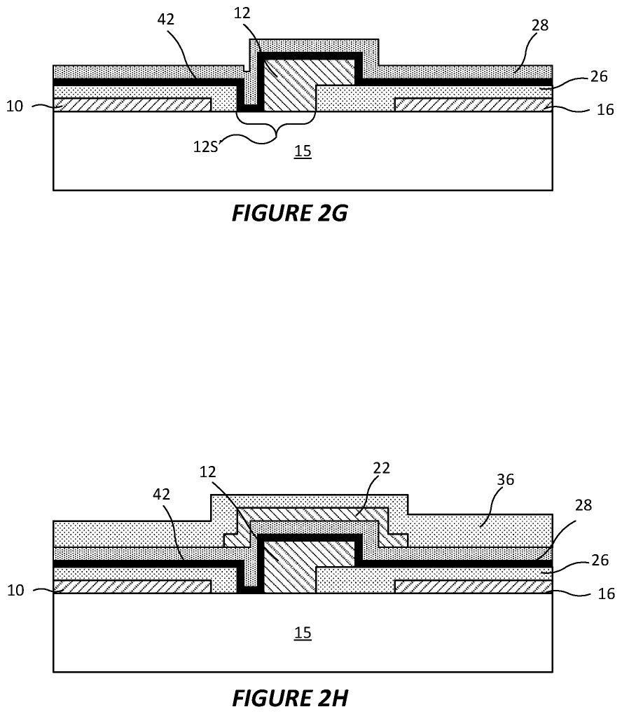

Operations of forming a depletion mode GaN HEMT device 10A are illustrated in FIGS. 2A to 2H. It will be appreciated that the illustrations shown in FIGS. 2A to 2H are not drawn to scale, as certain features of the structure are exaggerated for illustrative purposes. Moreover, it will be appreciated that the various features illustrated in FIGS. 2A to 2H are shown in idealized form with straight edges and sharp corners, a device produced in an actual production environment will have variations in texture and shape, such as uneven thicknesses, rounded corners, etc., due to the manufacturing processes used to form the features of the device.

Referring to FIG. 2A, an epiwafer 15 is provided. A source contact 10 and drain contact 16 are formed on a surface of the epiwafer 15. Referring to FIG. 2B, a surface dielectric layer 26 is formed on the surface of the epiwafer 15 above the source contact 10 and the drain contact 16. The surface dielectric layer 26 may comprise SiN. Referring to FIG. 2C, an opening 26A is formed in the surface dielectric layer 26 via conventional lithographic techniques. The opening 26A has a width w, which may be about 0.1 microns or greater. The opening 26A exposes a portion 12S′ of the surface of the epiwafer 15 having the corresponding width w.

Referring to FIG. 2D, a photolithographic mask 13 is formed on the structure. The mask 13 is patterned such that an opening 13A is formed in the mask 13 to expose a region 12S of the surface of the epiwafer 15 and to partially expose a portion of the surface dielectric layer 15 adjacent the drain contact 16. The opening 13A in the mask 13 may be about 0.1 microns or greater, and in particular embodiments may be about 0.4 microns. The opening 13A is offset relative to the opening 26A in the surface dielectric layer 26 towards the drain contact 16 by a distance of d, which may be, for example, about 0.05 to 0.08 microns. Thus, a region 12S of the surface of the epiwafer 15 exposed by the opening 13A in the mask 13 may have a width of about w−d. This distance w−d defines the gate length the device according to some embodiments. In some embodiments, the distance w−d may be less than 0.1 microns, and in particular may be about 0.07 microns or less.

In particular, referring to FIG. 2E, after the mask 13 is formed, a metal layer 62 is blanket deposited over the structure including into the opening 13A. The portion of the metal layer 62 that is in the opening 13A forms a gate contact 12 that contacts the surface of the epiwafer 15 in the region 12S. The gate 12 extends onto the exposed portion of the surface dielectric layer 26 adjacent the drain contact 16 such that the gate contact 12 forms a gamma-gate (r-gate) arrangement including a main contact portion 12M and a gamma portion 12G that is separated from the epiwafer 15 by the surface dielectric layer 26 and extends from the main contact portion 12M towards the drain contact 16. Because the gate contact 12 contacts the epiwafer 15 directly with no intervening insulation layer that can cause the 2DEG to be depleted of charges, the HEMT device formed according to this embodiment may be a depletion mode device that is normally ON.

The main contact portion 12M of the gate contact 12 may have a width of less than about 0.1 microns, and in particular may be about 0.07 microns or less. The gamma portion 12G of the contact 12 may have a width greater than about 0.1 microns, and in particular may have a width of about 0.35 microns.

Referring to FIG. 2F, the mask 13 and portions of the metal layer 62 on the mask are then removed using a lift-off procedure, leaving the gate contact 12 on the epiwafer 15 and surface dielectric layer 26.

Referring to FIG. 2G, an insulation layer 42 is then formed over the structure. The insulation layer 42 may comprise, for example, aluminum oxide and may have a thickness of about 10 nm to about 50 nm. In particular, the insulation layer may have a thickness of about 10 nm. The insulation layer 42 may extend onto the surface of the epiwafer 15 in a portion of the region 12S′ that is not covered by the gate contact 12.

A second dielectric layer 28 is then formed over the structure to cover the insulation layer 42. The second dielectric layer 28 may comprise SiN.

Referring to FIG. 2H, a field plate 22 is formed over the gate contact 12. The field plate is connected to the gate contact 12 via a gate feed line area (not shown), and is separated from the gate contact 12 by the second dielectric layer 28. A third dielectric layer 36 is formed over the second dielectric layer 28 and the field plate 22.

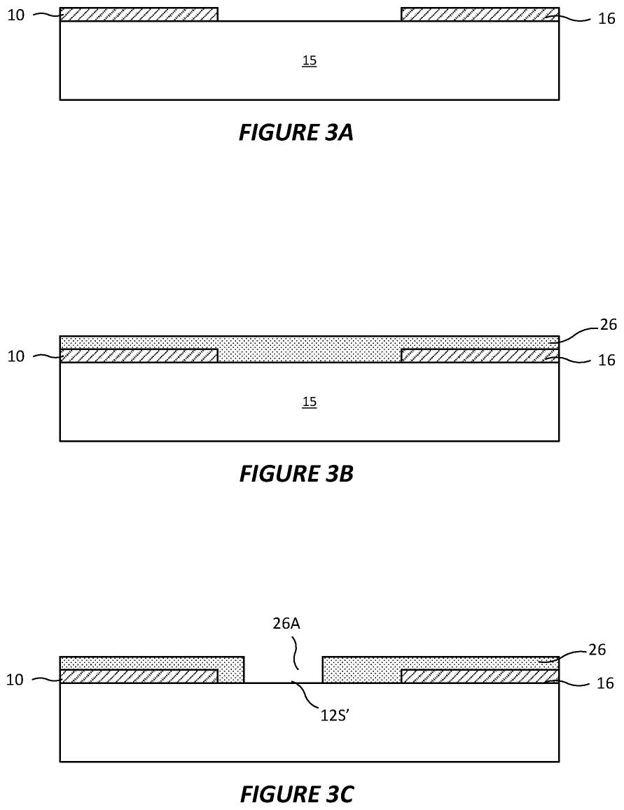

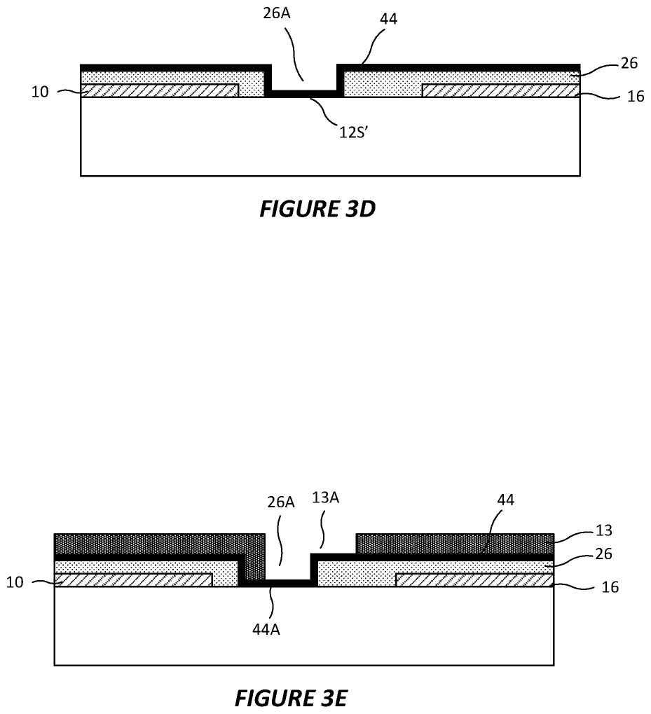

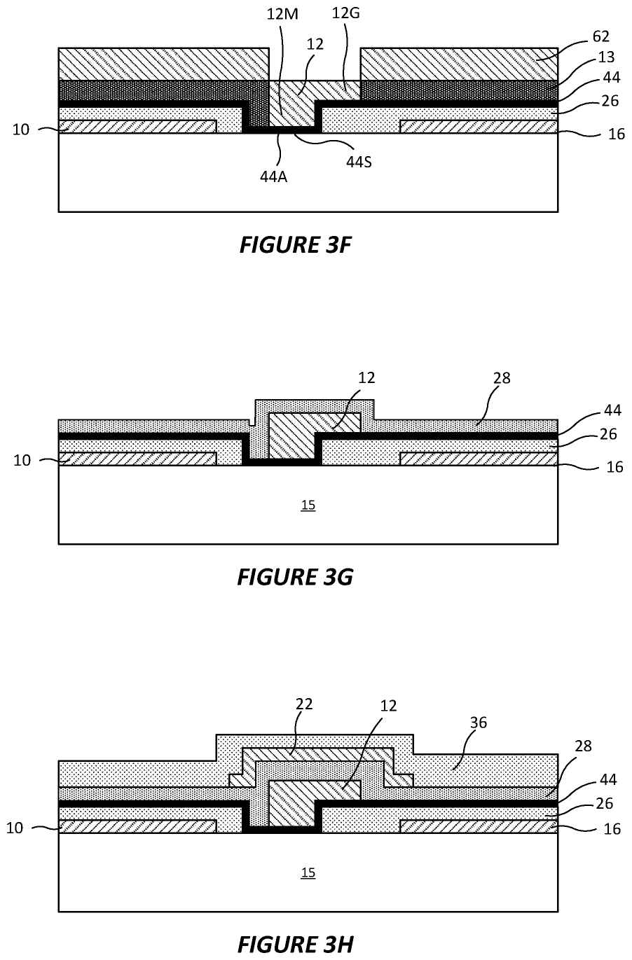

Operations of forming an enhancement mode GaN HEMT device 10B are illustrated in FIGS. 3A to 3H. It will be appreciated that the illustrations shown in FIGS. 3A to 3H are not drawn to scale, as certain features of the structure are exaggerated for illustrative purposes. Moreover, it will be appreciated that the various features illustrated in FIGS. 3A to 3H are shown in idealized form with straight edges and sharp corners, a device produced in an actual production environment will have variations in texture and shape, such as uneven thicknesses, rounded corners, etc., due to the manufacturing processes used to form the features of the device.

Referring to FIG. 3A, an epiwafer 15 is provided. A source contact 10 and drain contact 16 are formed on a surface of the epiwafer 15. Referring to FIG. 3B, a surface dielectric layer 26 is formed on the surface of the epiwafer 15 above the source contact 10 and the drain contact 16. The surface dielectric layer 26 may comprise SiN. Referring to FIG. 3C, an opening 26A is formed in the surface dielectric layer 26 via conventional lithographic techniques. The opening 26A has a width w, which may be about 0.1 microns or greater. The opening 26A exposes a portion 12S′ of the surface of the epiwafer 15 having the corresponding width w. The exposed portion 12S′ of the surface may be treated with a plasma treatment using F ions.

Referring to FIG. 3D, an insulation layer 44 is then formed over the structure. The insulation layer 44 may comprise, for example, aluminum oxide and may have a thickness of about 10 nm to about 50 nm. In particular, the insulation layer may have a thickness of about 10 nm. A recessed portion 44A of the insulation layer 44 may extend onto the surface of the epiwafer 15 in the region 12S′. The material composition and/or thickness of the insulation layer may be selected to deplete the 2DEG of charge carriers under zero bias conditions, so that the HEMT device will operate as an enhancement mode device that is a normally OFF device. In some embodiments, the insulation layer 44 may have fixed charge carriers stored therein that operate to deplete the 2DEG region beneath the insulation layer 44 to be depleted of charge carriers.

Referring to FIG. 3E, a photolithographic mask 13 is formed on the structure. The mask 13 is patterned such that an opening 13A is formed in the mask 13 to expose a portion of the insulation layer 44 including a recessed portion 44A of the insulation layer 44 in the opening 26A and a portion of the insulating layer 44 on the surface dielectric layer 15 adjacent the drain contact 16. The opening 13A in the mask 13 may be about 0.1 microns or greater, and in particular embodiments may be about 0.4 microns. The opening 13A is offset relative to the opening 26A in the surface dielectric layer 26 towards the drain contact 16 by a distance of d, which may be, for example, about 0.05 to 0.08 microns. Thus, a region 44S of the insulation layer 44 exposed by the opening 13A in the mask 13 may have a width of about w−d. This distance w−d defines the gate length of the device according to some embodiments. In some embodiments, the distance w−d may be less than 0.1 microns, and in particular may be about 0.07 microns or less.

In particular, referring to FIG. 3F, after the mask 13 is formed, a metal layer 62 is blanket deposited over the structure including into the opening 13A. The portion of the metal layer 62 that is in the opening 13A forms a gate contact 12 that contacts the insulation layer 44 in the region 44S. The gate 12 extends over the portion of the surface dielectric layer 26 adjacent the drain contact 16 such that the gate contact 12 forms a gamma-gate (r-gate) arrangement including a main contact portion 12M and a gamma portion 12G that is separated from the epiwafer 15 by the surface dielectric layer 26 and extends from the main contact portion 12M towards the drain contact 16.

The main contact portion 12M of the gate contact 12 may have a width of less than about 0.1 microns, and in particular may be about 0.07 microns or less. The gamma portion 12G of the contact 12 may have a width greater than about 0.1 microns, and in particular may have a width of about 0.35 microns.

Referring to FIG. 3G, the mask 13 and portions of the metal layer 62 on the mask are then removed using a lift-off procedure, leaving the gate contact 12 on the epiwafer 15 and surface dielectric layer 26.

A second dielectric layer 28 is then formed over the structure to cover the insulation layer 44. The second dielectric layer 28 may comprise SiN.

Referring to FIG. 3H, a field plate 22 is formed over the gate contact 12. The field plate is connected to the gate contact 12 via a gate feed line area (not shown), and is separated from the gate contact 12 by the second dielectric layer 28.

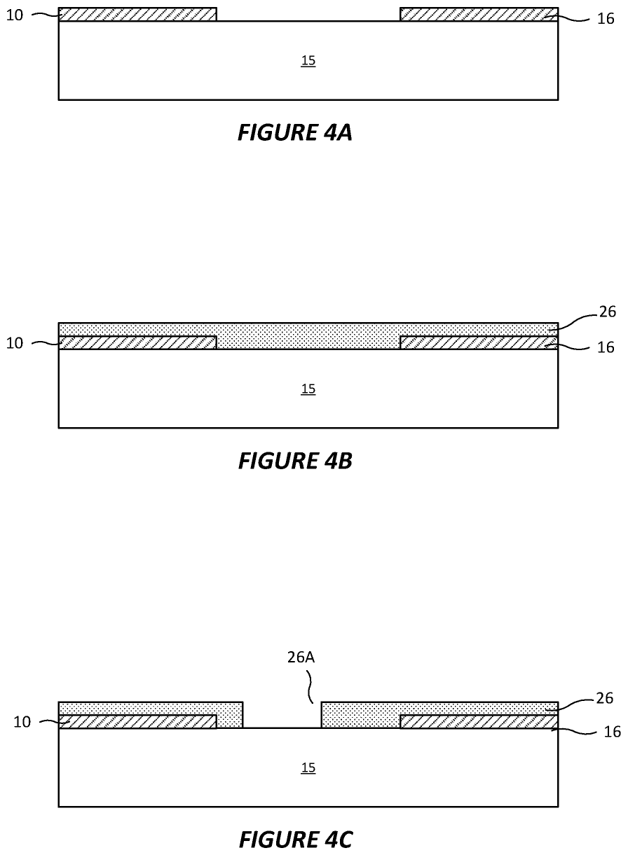

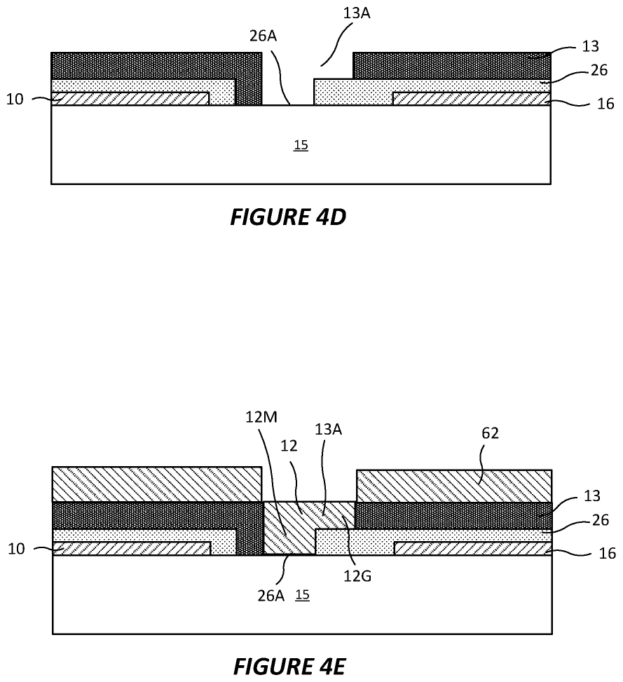

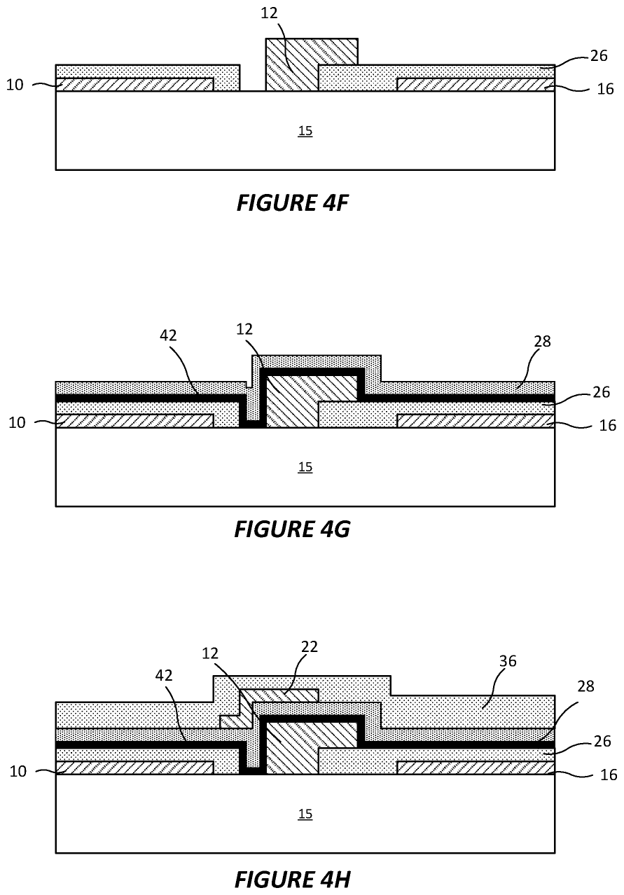

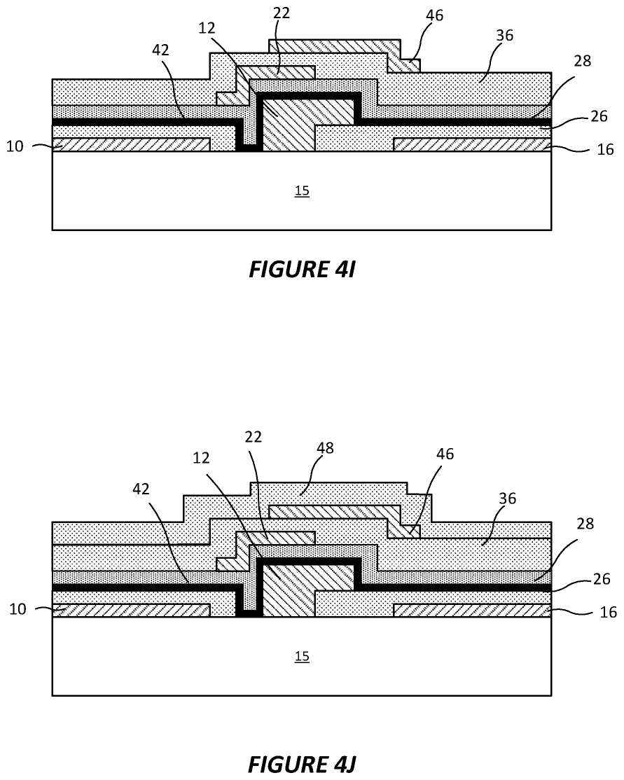

Operations of forming a depletion mode HEMT 10C according to further embodiments are illustrated in FIGS. 4A to 4J. It will be appreciated that the illustrations shown in FIGS. 4A to 4H are not drawn to scale, as certain features of the structure are exaggerated for illustrative purposes. Moreover, it will be appreciated that the various features illustrated in FIGS. 4A to 4H are shown in idealized form with straight edges and sharp corners, a device produced in an actual production environment will have variations in texture and shape, such as uneven thicknesses, rounded corners, etc., due to the manufacturing processes used to form the features of the device.

Referring to FIG. 4A, an epiwafer 15 is provided. A source contact 10 and drain contact 16 are formed on a surface of the epiwafer 15. Referring to FIG. 4B, a surface dielectric layer 26 is formed on the surface of the epiwafer 15 above the source contact 10 and the drain contact 16. The surface dielectric layer 26 may comprise SiN. Referring to FIG. 4C, an opening 26A is formed in the surface dielectric layer 26 via conventional lithographic techniques. The opening 26A has a width w, which may be about 0.1 microns or greater. The opening 26A exposes a portion 12S′ of the surface of the epiwafer 15 having the corresponding width w.

Referring to FIG. 4D, a photolithographic mask 13 is formed on the structure. The mask 13 is patterned such that an opening 13A is formed in the mask 13 to expose a region 12S of the surface of the epiwafer 15 and to partially expose a portion of the surface dielectric layer 26 adjacent the drain contact 16. The opening 13A in the mask 13 may be about 0.1 microns or greater, and in particular embodiments may be about 0.4 microns. The opening 13A is offset relative to the opening 26A in the surface dielectric layer 26 towards the drain contact 16 by a distance of d, which may be, for example, about 0.05 to 0.08 microns. Thus, a region 26A of the surface of the epiwafer 15 exposed by the opening 13A in the mask 13 may have a width of about w−d. This distance w−d defines the gate length of the device according to some embodiments. In some embodiments, the distance w−d may be less than 0.1 microns, and in particular may be about 0.07 microns or less.

In particular, referring to FIG. 4E, after the mask 13 is formed, a metal layer 62 is blanket deposited over the structure including into the opening 13A. The portion of the metal layer 62 that is in the opening 13A forms a gate contact 12 that contacts the surface of the epiwafer 15 in the region 26A. The gate 12 extends onto the exposed portion of the surface dielectric layer 26 adjacent the drain contact 16 such that the gate contact 12 forms a gamma-gate (r-gate) arrangement including a main contact portion 12M and a gamma portion 12G that is separated from the epiwafer 15 by the surface dielectric layer 26 and extends from the main contact portion 12M towards the drain contact 16.

The main contact portion 12M of the gate contact 12 may have a width of less than about 0.1 microns, and in particular may be about 0.07 microns or less. The gamma portion 12G of the contact 12 may have a width greater than about 0.1 microns, and in particular may have a width of about 0.35 microns.

Referring to FIG. 4F, the mask 13 and portions of the metal layer 62 on the mask are then removed using a lift-off procedure, leaving the gate contact 12 on the epiwafer 15 and surface dielectric layer 26.

Referring to FIG. 4G, an insulation layer 42 is then formed over the structure. The insulation layer 42 may comprise, for example, aluminum oxide and may have a thickness of about 10 nm to about 50 nm. In particular, the insulation layer may have a thickness of about 10 nm. The insulation layer 42 may extend onto the surface of the epiwafer 15 in a portion of the region 26A that is not covered by the gate contact 12.

A second dielectric layer 28 is then formed over the structure to cover the insulation layer 42. The second dielectric layer 28 may comprise SiN.

Referring to FIG. 4H, a field plate 22 is formed over the gate contact 12. The field plate is connected to the gate contact 12 via a gate feed line area (not shown), and is separated from the gate contact 12 by the second dielectric layer 28. A third dielectric layer 36 is formed over the second dielectric layer 28 and the field plate 22.

Referring to FIG. 4I, a second field plate 46 is formed on the third dielectric layer 36. The second field plate 46 is connected to the source contact 10 via the source metallization. The second field plate 46 may partially overlap the first field plate 22 and the gate contact 12, and may extend over a region of the epiwafer 15 between the gate contact 12 and the drain contact 16.

Referring to FIG. 4J, a fourth dielectric layer 48 is formed over the third dielectric layer 36 and the second field plate 46.

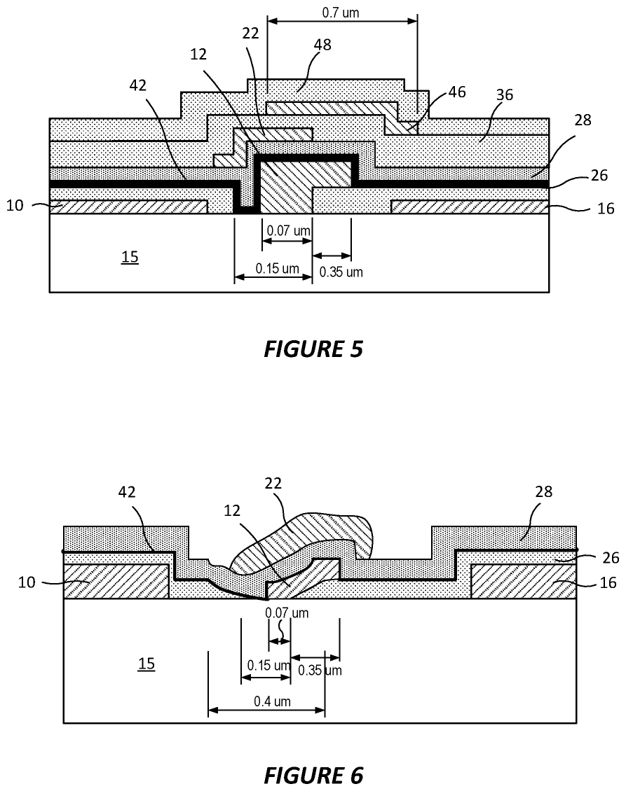

FIG. 5 is a cross section of a depletion mode HEMT device structure 10C including a first field plate 22 and a second field plate 46. In particular, FIG. 5 illustrates some representative dimensions of the HEMT device structure 10C. For example, the gate contact 12 of the device structure 10C may have a gate length Lg of about 0.07 microns. The “gamma” portion of the gate contact 12 may extend towards the drain contact 16 by a distance of about 0.35 microns. The region 12S of the surface of the epiwafer 15 in which the gate is formed may have a total width of about 0.15 microns. The first field plate 22 may have a width of about 0.5 microns, and the second field plate 46 may have a width of about 0.7 microns.

FIG. 6 is a more realistic drawing of a depletion mode HEMT structure according to some embodiments. As illustrated in FIG. 6, various features of the HEMT structure have variations in texture and shape, such as uneven thicknesses, rounded corners, etc., due to the manufacturing processes used to form the features of the device. In particular, the gate contact 12 may have slanted portions, and the various dielectric layers in the structure may have uneven thicknesses and/or textured surfaces.

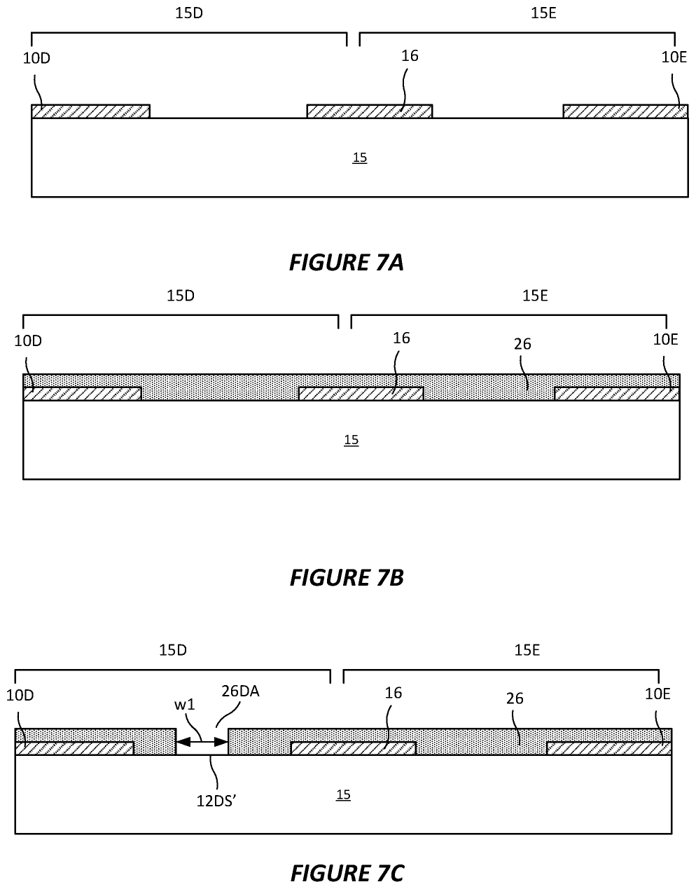

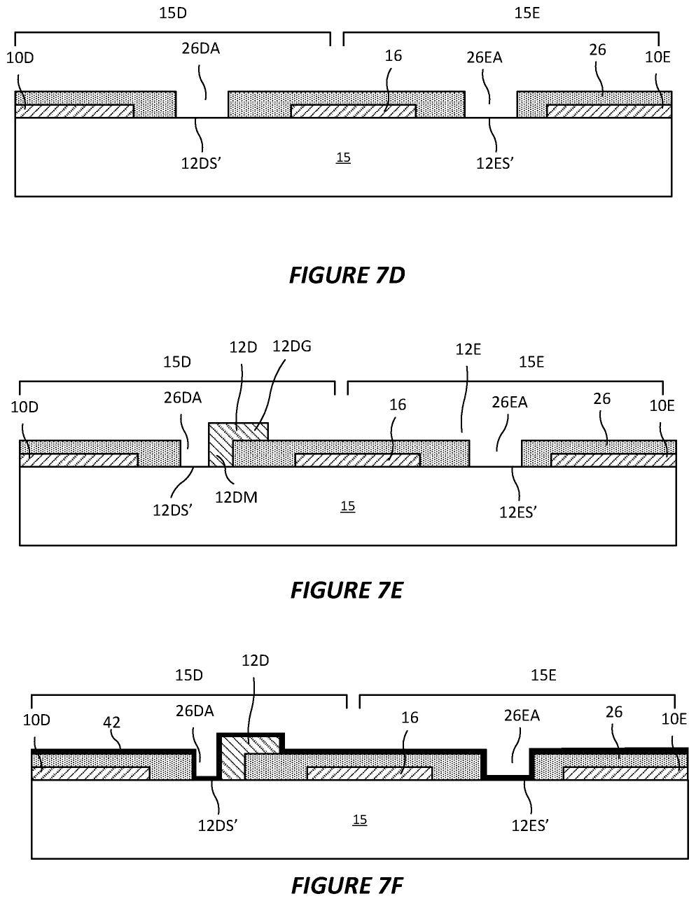

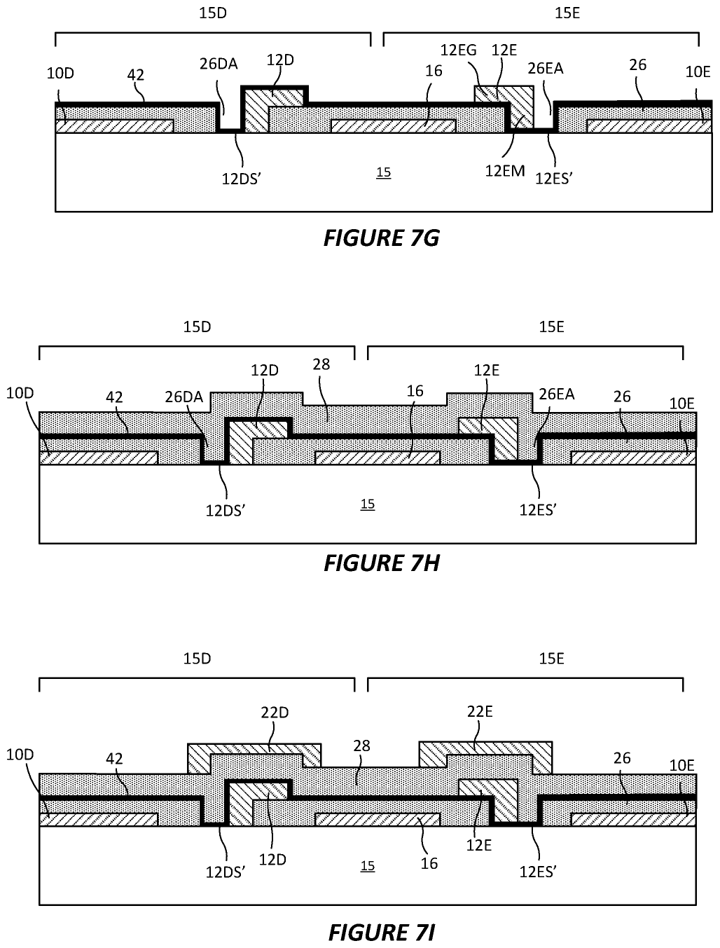

FIGS. 7A to 7J illustrate operations for simultaneously forming an enhancement mode HEMT device structure and a depletion mode device structure on the same epiwafer 15. It will be appreciated that the illustrations shown in FIGS. 7A to 7H are not drawn to scale, as certain features of the structure are exaggerated for illustrative purposes. Moreover, it will be appreciated that the various features illustrated in FIGS. 7A to 7H are shown in idealized form with straight edges and sharp corners, a device produced in an actual production environment will have variations in texture and shape, such as uneven thicknesses, rounded corners, etc., due to the manufacturing processes used to form the features of the device.

Referring to FIG. 7A, an epiwafer 15 is provided. A first source contact 10D for a depletion mode HEMT and a second source contact 10E for an enhancement mode HEMT are formed on the epiwafer 15. A common drain contact 16 is formed on a surface of the epiwafer 15 between the first source contact 10D and the second source contact 10E. The depletion mode HEMT is formed in a first region 15D of the epiwafer 15, while the enhancement mode HEMT is formed in a second region 15E of the epiwafer 15.

In FIGS. 7A to 7J, the enhancement mode HEMT and depletion mode HEMT are illustrated as having a common drain contact 16. However, it will be appreciated that embodiments described herein may be applicable to the formation of enhancement and depletion mode HEMTs on the same epiwafer 15 that do not share a common drain contact 16.

Referring to FIG. 7B, a surface dielectric layer 26 is formed on the surface of the epiwafer 15 above the source contacts 10E, 10D and the drain contact 16. The surface dielectric layer 26 may comprise SiN.

Referring to FIG. 7C, an opening 26DA is formed in the surface dielectric layer 26 via conventional lithographic techniques in the first region 15D between the source contact 10D and the drain contact 16. The opening 26DA has a width w1, which may be about 0.1 microns or greater. The opening 26DA exposes a portion 12DS′ of the surface of the epiwafer 15 having the corresponding width w1.

Referring to FIG. 7D, an opening 26EA is formed in the surface dielectric layer 26 via conventional lithographic techniques in the second region 15E between the source contact 10E and the drain contact 16. The opening 26EA has a width w2, which may be about 0.1 microns or greater. The opening 26EA exposes a portion 12ES′ of the surface of the epiwafer 15 having the corresponding width w2.

Referring to FIG. 7E, a first gamma gate 12D is formed in the opening 26DA in the first region 15D of the epiwafer 15, for example, using the offset mask photolithography as discussed above in connection with FIG. 2D. The first gamma gate 12D may have a gate length Lg of less than 0.1 microns, and in particular embodiments may be about 0.07 microns.

The first gamma gate 12D may have a gamma portion 12DG that is separated from the epiwafer 15 by the surface dielectric layer 26 and extends from the main contact portion 12DM of the gate contact 12D towards the drain contact 16.

Referring to FIG. 7F, an insulation layer 42 is then formed over the structure. The insulation layer 42 may comprise, for example, aluminum oxide and may have a thickness of about 10 nm to about 50 nm. In particular, the insulation layer may have a thickness of about 10 nm. The insulation layer 42 may extend onto the surface of the epiwafer 15 in a portion of the region 12DS′ that is not covered by the gate contact 12D. The insulation layer 42 may also extend into the opening 26EA in the second region 15E of the epiwafer 15.

Referring to FIG. 7G, a second gamma gate 12E is formed in the opening 12EA in the second region 15E of the epiwafer 15, for example, using the offset mask photolithography as discussed above in connection with FIG. 3E. The second gamma gate 12E may have a gate length Lg of less than 0.1 microns, and in particular embodiments may be about 0.07 microns. The second gamma gate 12E may have a gamma portion 12EG that is separated from the epiwafer 15 by the surface dielectric layer 26 and the insulation layer 42, and extends from the main contact portion 12EM of the gate contact 12E towards the drain contact 16.

Referring to FIG. 7H, a second dielectric layer 28 is then formed over the structure to cover the insulation layer 42. The second dielectric layer 28 may comprise SiN.

Referring to FIG. 7I, a first field plate 22D is formed over the first gate contact 12D in the first region 15D, and a second field plate 22E is formed over the second gate contact 12E in the second region 15E. The first field plate 22D is connected to the first gate contact 12D via a gate feed line area (not shown), and is separated from the gate contact 12 by the second dielectric layer 28 and the insulation layer 42. The second field plate 22E is connected to the second gate contact 12E via a gate feed line area (not shown), and is separated from the gate contact 12E by the second dielectric layer 28.

Referring to FIG. 7J, a third dielectric layer 36 is formed over the second dielectric layer 28 and the field plates 22E, 22D.

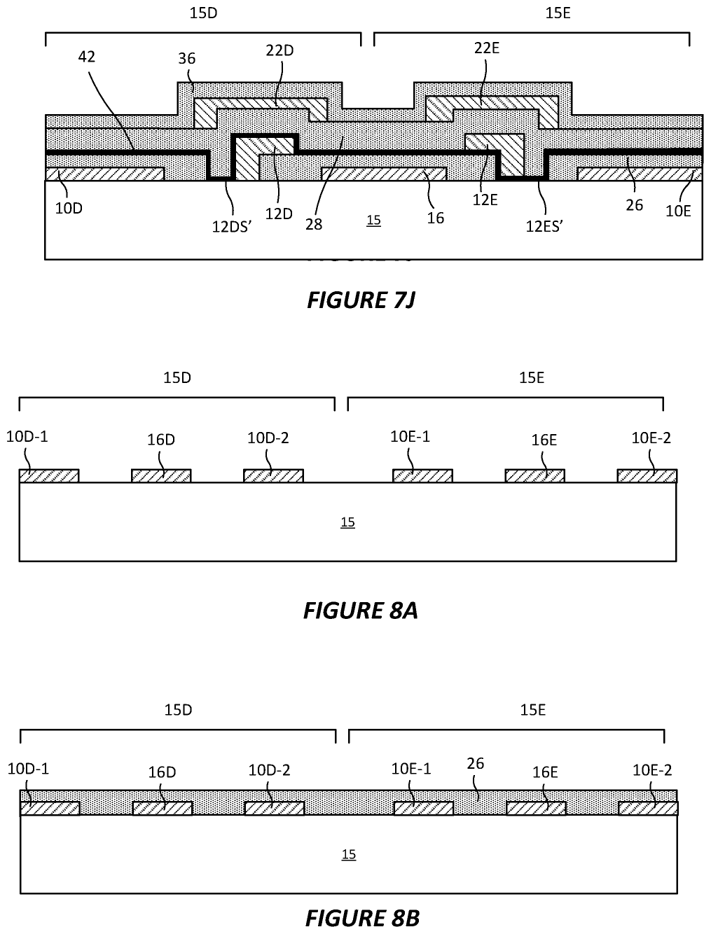

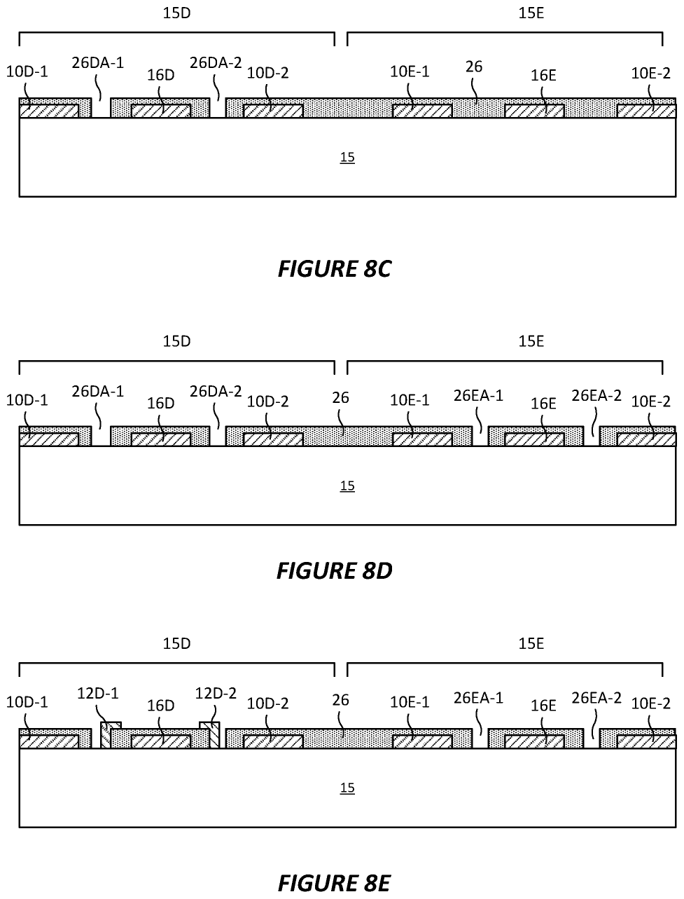

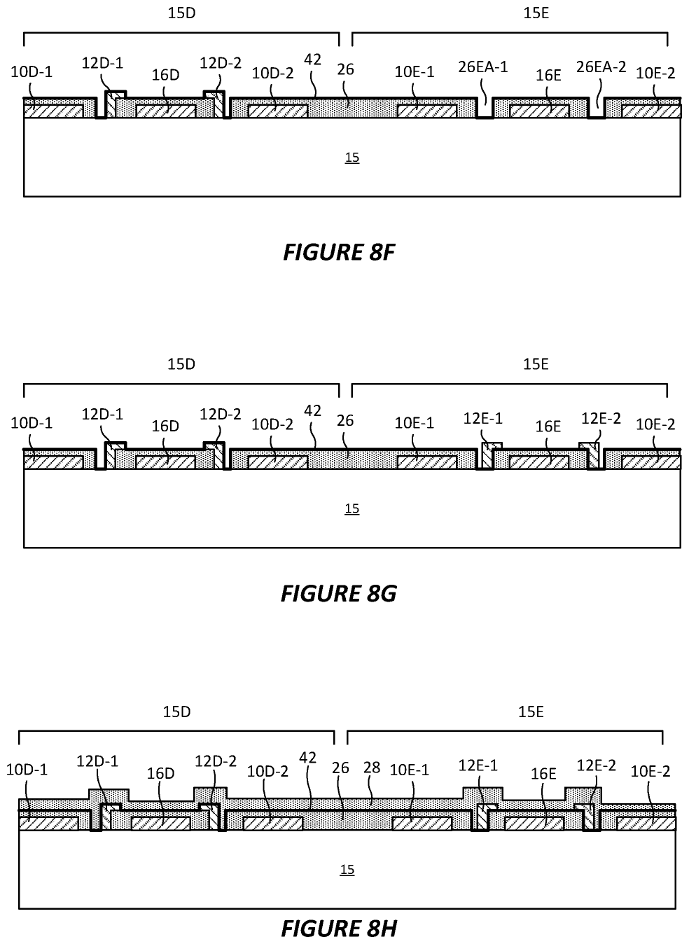

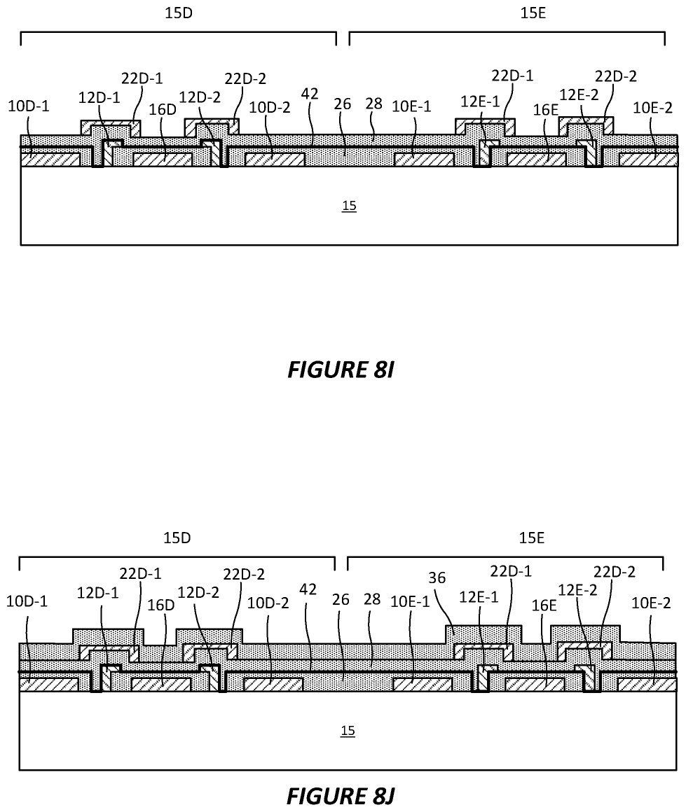

FIGS. 8A to 8J illustrate operations for simultaneously forming an enhancement mode HEMT device structure and a depletion mode device structure on the same epi wafer 15. It will be appreciated that the illustrations shown in FIGS. 8A to 8J are not drawn to scale, as certain features of the structure are exaggerated for illustrative purposes. Moreover, it will be appreciated that the various features illustrated in FIGS. 8A to 8J are shown in idealized form with straight edges and sharp corners, a device produced in an actual production environment will have variations in texture and shape, such as uneven thicknesses, rounded corners, etc., due to the manufacturing processes used to form the features of the device.

In the embodiments illustrated in FIGS. 8A to 8J, a pair of depletion mode HEMTs are formed in a first region 15D of the epiwafer 15, while a pair of enhancement mode HEMTs are formed in a second region 15E of the epiwafer.

Referring to FIG. 8A, an epiwafer 15 is provided. A first source contact 10D-1 for a first depletion mode HEMT and a second source contact 10D-2 for a second depletion mode HEMT are formed in a first region 15D of the epiwafer 15. A common drain contact 16D is formed on a surface of the epiwafer 15 between the first source contact 10D-1 and the second source contact 10D-2. A first source contact 10E-1 for a first enhancement mode HEMT and a second source contact 10E-2 for an enhancement mode HEMT are formed in a second region 15E of the epiwafer 15. A common drain contact 16E is formed on a surface of the epiwafer 15 between the first source contact 10E-1 and the second source contact 10E-2.

Referring to FIG. 8B, a surface dielectric layer 26 is formed on the surface of the epiwafer 15 above the source contacts 10D-1, 10D-2, 10E-1, 10E-2 and the drain contacts 16D, 16E. The surface dielectric layer 26 may comprise SiN. Referring to FIG. 8C, an opening 26DA is formed in the surface dielectric layer 26 via conventional lithographic techniques in the first region 15D between the source contact 10D and the drain contact 16. The opening 26DA has a width w, which may be about 0.1 microns or greater. The opening 26DA exposes a portion 12DS′ of the surface of the epiwafer 15 having the corresponding width w2.

Referring to FIG. 8C, openings 26DA-1, 26DA-2 are formed in the surface dielectric layer 26 via conventional lithographic techniques in the first region 15D. The openings 26DA-1, 26DA-2 may be similar to the opening 26DA described above with regard to FIGS. 7A to 7I.

Referring to FIG. 8D, openings 26EA-1, 26EA-2 are formed in the surface dielectric layer 26 via conventional lithographic techniques in the second region 15E. The openings 26EA-1, 26EA-2 may be similar to the opening 26EA described above with regard to FIGS. 7A to 7I.

Referring to FIG. 8E, first gamma gates 12D-1, 12D-2 are formed in the openings 12DA-1 12DA-2 in the first region 15D of the epiwafer 15, for example, using the offset mask photolithography as discussed above in connection with FIG. 2D. The first gamma gates 12D-1, 12D-2 may be formed in a similar manner as the first gamma gate 12D described in connection with FIGS. 7A to 7I.

Referring to FIG. 8F, an insulation layer 42 is then formed over the structure.

Referring to FIG. 8G, second gamma gates 12E-1, 12E-2 are formed in the openings 12EA-1, 12EA-2 in the second region 15E of the epiwafer 15, for example, using the offset mask photolithography as discussed above in connection with FIG. 3E. The second gamma gates 12E-1, 12E-2 may be similar to the second gamma gate 12E described in connection with FIGS. 7A to 7I.

Referring to FIG. 8H, a second dielectric layer 28 is then formed over the structure to cover the insulation layer 42. The second dielectric layer 28 may comprise SiN.

Referring to FIG. 8I, first field plates 22D-1, 22D-2 are formed over the first gate contacts 12D-1, 12D-2 in the first region 15D, and second field plates 22E-1, 22E-2 are formed over the second gate contacts 12E-1, 12E-2 in the second region 15E.

Referring to FIG. 8J, a third dielectric layer 36 is formed over the second dielectric layer 28 and the field plate 22.

Transistor devices including contacts as described herein may be used in amplifiers that operate in a wide variety of different frequency bands. In some embodiments, the RF power amplifiers incorporating transistor devices as described herein may be configured to operate at frequencies greater than 1 GHz. In other embodiments, the RF power amplifiers may be configured to operate at frequencies greater than 2.5 GHz. In still other embodiments, the RF power amplifiers may be configured to operate at frequencies greater than 3.1 GHz. In yet additional embodiments, the RF power amplifiers may be configured to operate at frequencies greater than 5 GHz. In some embodiments, the RF power amplifiers may be configured to operate in at least one of the 2.5-2.7 GHz, 3.4-4.2 GHz, 5.1-5.8 GHz, 12-18 GHz, 18-27 GHz, 27-40 GHz or 40-75 GHz frequency bands or sub-portions thereof.

Although embodiments of the inventive concepts have been discussed above with respect to HEMT devices, it will be understood that the inventive concepts described herein may be applied to other types of semiconductor devices, such as MOSFETs, DMOS transistors, and/or laterally diffused MOS (LDMOS) transistors.

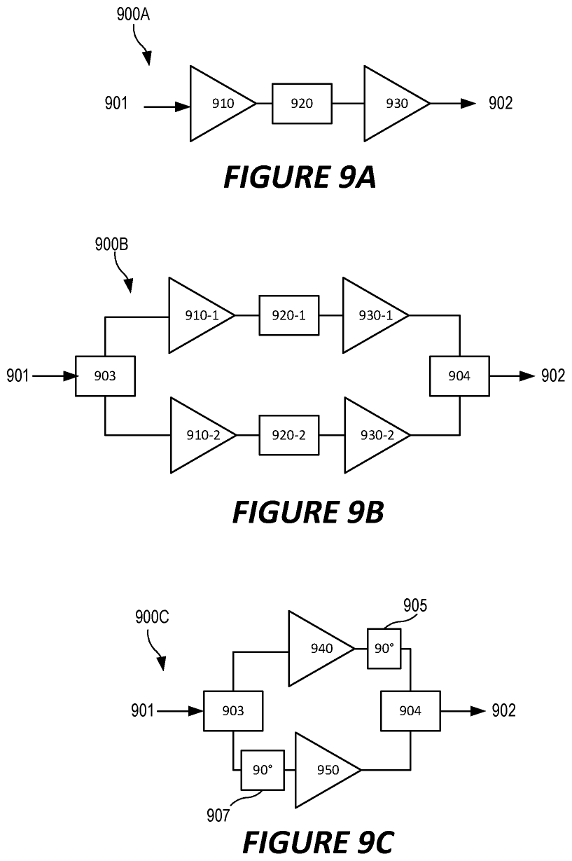

RF power amplifiers incorporating transistor devices described herein can be used in standalone RF power amplifiers and/or in multiple RF power amplifiers. Examples of how the RF power amplifiers according to some embodiments may be used in applications that include multiple amplifiers will be discussed with reference to FIGS. 9A-9C.

Referring to FIG. 9A, an RF power amplifier 900A is schematically illustrated that includes a pre-amplifier 910 and a main amplifier 930 that are electrically connected in series. As shown in FIG. 9A, RF power amplifier 900A includes an RF input 901, the pre-amplifier 910, an inter-stage impedance matching network 920, the main amplifier 930, and an RF output 902. The inter-stage impedance matching network 920 may include, for example, inductors and/or capacitors arranged in any appropriate configuration in order to form a circuit that improves the impedance match between the output of pre-amplifier 910 and the input of main amplifier 930. While not shown in FIG. 9A, RF power amplifier 900A may further include an input matching network that is interposed between RF input 901 and pre-amplifier 910, and/or an output matching network that is interposed between the main amplifier 930 and the RF output 902. The RF power amplifiers according to embodiments may be used to implement either or both of the pre-amplifier 910 and the main amplifier 930.

Referring to FIG. 9B, an RF power amplifier 900B is schematically illustrated that includes an RF input 901, a pair of pre-amplifiers 910-1, 910-2, a pair of inter-stage impedance matching networks 920-1, 920-2, a pair of main amplifiers 930-1, 930-2, and an RF output 902. A splitter 903 and a combiner 904 are also provided. Pre-amplifier 910-1 and main amplifier 930-1 (which are electrically connected in series) are arranged electrically in parallel with pre-amplifier 910-2 and main amplifier 930-2 (which are electrically connected in series). As with the RF power amplifier 900A of FIG. 9A, RF power amplifier 900B may further include an input matching network that is interposed between RF input 901 and pre-amplifiers 910-1, 910-2, and/or an output matching network that is interposed between the main amplifiers 930-1, 930-2 and the RF output 902.

As shown in FIG. 9C, the RF power amplifiers according to some embodiments may also be used to implement Doherty amplifiers. As is known in the art, a Doherty amplifier circuit includes first and second (or more) power-combined amplifiers. The first amplifier is referred to as the “main” or “carrier” amplifier and the second amplifier is referred to as the “peaking” amplifier. The two amplifiers may be biased differently. For example, the main amplifier may comprise a Class AB or a Class B amplifier while the peaking amplifier may be a Class C amplifier in one common Doherty amplifier implementation. The Doherty amplifier may operate more efficiently than balanced amplifiers when operating at power levels that are backed off from saturation. An RF signal input to a Doherty amplifier is split (e.g., using a quadrature coupler), and the outputs of the two amplifiers are combined. The main amplifier is configured to turn on first (i.e., at lower input power levels) and hence only the main amplifier will operate at lower power levels. As the input power level is increased towards saturation, the peaking amplifier turns on and the input RF signal is split between the main and peaking amplifiers.

As shown in FIG. 9C, the Doherty RF power amplifier 900C includes an RF input 901, an input splitter 903, a main amplifier 940, a peaking amplifier 950, an output combiner 904 and an RF output 902. The Doherty RF power amplifier 900C includes a 90° transformer 907 at the input of the peaking amplifier 950 and a 90° transformer 905 at the input of the main amplifier 940 , and may optionally include input matching networks and/or an output matching networks (not shown). The main amplifier 940 and/or the peaking amplifier 850 may be implemented using any of the above-described RF power amplifiers according to embodiments.

The RF power amplifiers according to embodiments may be formed as discrete devices, or may be formed as part of a Monolithic Microwave Integrated Circuit (MMIC). A MMIC refers to an integrated circuit that operates on radio and/or microwave frequency signals in which all of the circuitry for a particular function is integrated into a single semiconductor chip. An example MMIC device is a power amplifier that includes associated matching circuits, feed networks and the like that are all implemented on a common substrate. MMIC transistor amplifiers typically include a plurality of unit cell HEMT transistors that are connected in parallel.

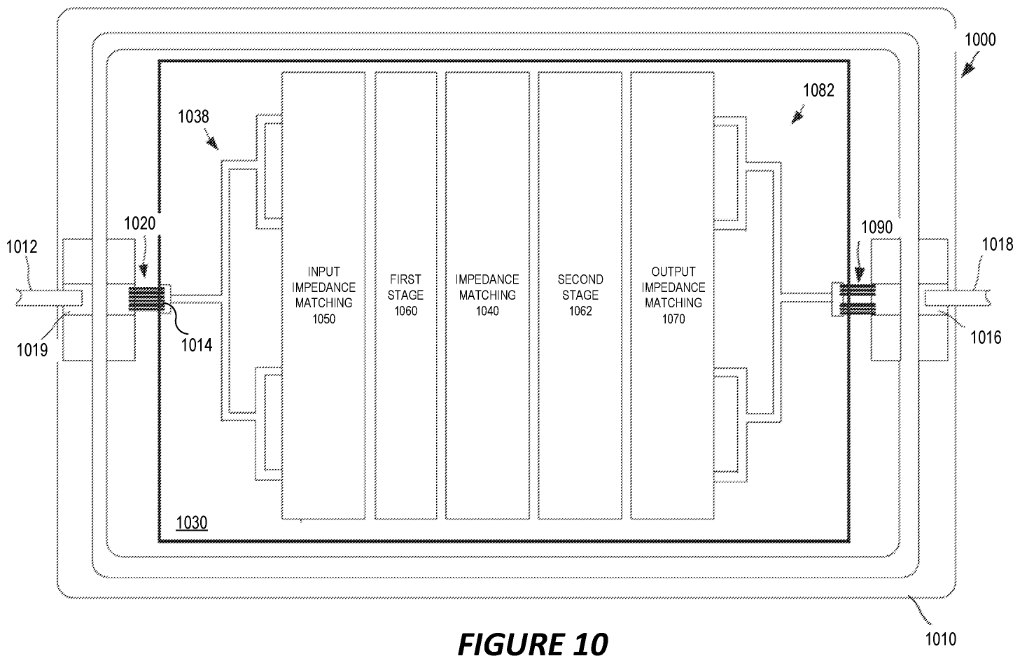

FIG. 10 is a plan view of a MMIC RF power amplifier 1000 according to embodiments of the present inventive concepts. As shown in FIG. 10, the MMIC RF power amplifier 1000 includes an integrated circuit chip 1030 that is contained within a package 1010. The package 1010 may comprise a protective housing that surrounds and protects the integrated circuit chip 1030. The package 1010 may be formed of, for example, a ceramic material.

The package 1010 includes an input lead 1012 and an output lead 1018. The input lead 1012 may be mounted to an input lead pad 1014 by, for example, soldering. One or more input bond wires 1020 may electrically connect the input lead pad 1014 to an input bond pad on the integrated circuit chip 1030. The integrated circuit chip 1030 includes an input feed network 1038, an input impedance matching network 1050, a first RF power amplifier stage 1060, an intermediate impedance matching network 1040, a second RF power amplifier stage 1062, an output impedance matching stage 1070, and an output feed network 1082.

The package 1010 further includes an output lead 1018 that is connected to an output lead pad 1016 by, for example, soldering. One or more output bond wires 1090 may electrically connect the output lead pad 1016 to an output bond pad on the integrated circuit chip 1030. The first RF power amplifier stage 1060 and/or the second RF power amplifier stage 1062 may be implemented using any of the RF power amplifiers according to embodiments of the present inventive concepts.

The RF power amplifiers according to embodiments of the present inventive concepts may be designed to operate in a wide variety of different frequency bands. In some embodiments, these RF power amplifier dies may be configured to operate in at least one of the 0.6-2.7 GHz, 3.4-4.2 GHz, 5.1-5.8 GHz, 12-18 GHz, 18-27 GHz, 27-40 GHz or 90-75 GHz frequency bands or sub-portions thereof. The techniques according to embodiments of the present inventive concepts may be particularly advantageous for RF power amplifiers that operate at frequencies of 10 GHz and higher.

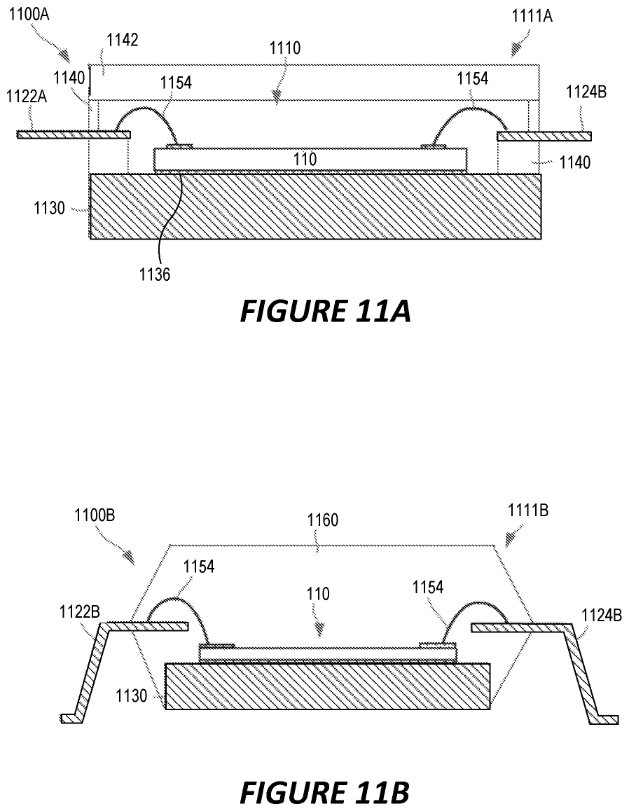

FIGS. 11A and 11B are schematic cross-sectional views illustrating several example transistor amplifier packages including RF power amplifier devices according to embodiments of the present inventive concepts.

FIG. 11A is a schematic side view of a packaged Group III nitride-based RF power amplifier 1100A. As shown in FIG. 11A, packaged RF power amplifier 1100A includes the RF power amplifier die 110 packaged in an open cavity package 1110A. The package 1110A includes metal gate leads 1122A, metal drain leads 1124A, a metal sub-mount 1130, sidewalls 1140 and a lid 1142.

The sub-mount 1130 may include materials configured to assist with the thermal management of the package 1100A. For example, the sub-mount 1130 may include copper and/or molybdenum. In some embodiments, the sub-mount 1130 may be composed of multiple layers and/or contain vias/interconnects. In an example embodiment, the sub-mount 1130 may be a multilayer copper/molybdenum/copper metal flange that comprises a core molybdenum layer with copper cladding layers on either major surface thereof. In some embodiments, the sub-mount 1130 may include a metal heat sink that is part of a lead frame or metal slug. The sidewalls 1140 and/or lid 1142 may be formed of or include an insulating material in some embodiments. For example, the sidewalls 1140 and/or lid 1142 may be formed of or include ceramic materials.

In some embodiments, the sidewalls 1140 and/or lid 1142 may be formed of, for example, Al2O3. The lid 1142 may be glued to the sidewalls 1140 using an epoxy glue. The sidewalls 1140 may be attached to the sub-mount 1130 via, for example, braising. The gate lead 1122A and the drain lead 1124A may be configured to extend through the sidewalls 1140, though embodiments of the present inventive concepts are not limited thereto.

The RF power amplifier die 110 is mounted on the upper surface of the metal sub-mount 1130 in an air-filled cavity 1112 defined by the metal sub-mount 1130, the ceramic sidewalls 1140 and the ceramic lid 1142. The gate and drain terminals of RF power amplifier die 110 may be on the top side of the semiconductor layer structure 150, while the source terminal is on the bottom side of the semiconductor layer structure 150.

The gate lead 1122A may be connected to the gate terminal of RF power amplifier die 110 by one or more bond wires 1154. Similarly, the drain lead 1124A may be connected to the drain terminal of RF power amplifier die 110 by one or more bond wires 1154. The source terminal may be mounted on the metal sub-mount 1130 using, for example, a conductive die attach material (not shown). The metal sub-mount 1130 may provide the electrical connection to the source terminal 1136 and may also serve as a heat dissipation structure that dissipates heat that is generated in the RF power amplifier die 110.

The heat is primarily generated in the upper portion of the RF power amplifier die 110 where relatively high current densities are generated. This heat may be transferred though from the semiconductor layer structure 150 to the source terminal and then to the metal sub-mount 1130.

FIG. 11B is a schematic side view of another packaged Group Ill nitride based RF power amplifier 1100B. RF power amplifier 1100B differs from RF power amplifier 1100A in that it includes a different package 1110B. The package 1110B includes a metal sub-mount 1130, as well as metal gate and drain leads 1122B, 1124B. RF power amplifier 1100B also includes a plastic over mold 1160 that at least partially surrounds the RF power amplifier die 110, the leads 1122B, 1124B, and the metal sub-mount 1130.

Other components of RF power amplifier 1100B may be the same as the like-numbered components of RF power amplifier 1100A and hence further description thereof will be omitted. While embodiments of the present inventive concepts are described above with respect to gallium nitride based RF power amplifiers, it will be appreciated that embodiments of the inventive concepts are not limited thereto. For example, the transistors described above may also be used as power transistors in switching and other applications.

Embodiments of the present inventive concepts have been described above with reference to the accompanying drawings, in which embodiments of the inventive concepts are shown. The inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. Like numbers refer to like elements throughout. In the specification and the figures, two-part reference numbers (i.e., two numbers separated by a dash, such as 100-1) may be used to identify like elements. When such two-part reference numbers are employed, the full reference numeral may be used to refer to a specific instance of the element, while the first part of the reference numeral may be used to refer to the elements collectively.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present inventive concepts. As used herein, the term “and/or” includes any and all combinations of one or more of the associated listed items. The terminology used herein is for the purpose of describing particular embodiments only and is not intended to be limiting of the inventive concepts. As used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Relative terms such as “below” or “above” or “upper” or “lower” or “horizontal” or “lateral” or “vertical” may be used herein to describe a relationship of one element, layer or region to another element, layer or region as illustrated in the figures.

Although embodiments of the inventive concepts have been described in considerable detail with reference to certain configurations thereof, other versions are possible. The field plates and gates can also have many different shapes and can be connected to the source contact in many different ways. Accordingly, the spirit and scope of the inventive concepts should not be limited to the specific embodiments described above.

1. A method of forming a transistor device, comprising:
providing an epiwafer comprising a substrate and one or more epitaxial layers;
forming source and drain contacts on a surface of the epiwafer;
forming a surface dielectric layer on the surface of the epiwafer;
forming a first opening in the surface dielectric layer, the opening having a first width and exposing a first region of the surface of the epiwafer;
forming a mask layer on the epiwafer, the mask layer having a second opening that is offset from the first opening, wherein the second opening exposes a portion of the first region of the surface of the epiwafer and a portion of the surface dielectric layer adjacent the first region of the surface of the epiwafer; and
forming a gate contact in the second opening.

2. The method of claim 1, wherein the portion of the first region of the surface of the epiwafer that is exposed by the second opening has a second width that is smaller than a first width of the first opening in the surface dielectric layer.

3. The method of claim 2, wherein the second width is less than about 0.1 microns.

4. The method of claim 3, wherein the second width is between about 0.05 microns and 0.08 microns.

5. The method of claim 4, wherein the second width is about 0.07 microns.

6. The method of claim 1, wherein the mask layer extends into the first opening in the surface dielectric layer, the method further comprising:
removing the mask layer;
wherein removing the mask layer exposes a portion of the first region of the surface of the epiwafer that was covered by the mask layer.

7. The method of claim 1, wherein the gate contact extends across the portion of the surface dielectric layer adjacent the first region of the surface of the epiwafer.

8. The method of claim 1, wherein the portion of the surface dielectric layer adjacent the first region of the surface of the epiwafer is between the first region of the surface of the epiwafer and the drain contact.

9. The method of claim 1, further comprising:
after forming the gate contact, forming an insulation layer on the epiwafer, wherein the insulation layer covers the gate contact and the surface dielectric layer.

10. The method of claim 9, wherein the insulation layer has a different material composition than the surface dielectric layer.

11. The method of claim 10, wherein the surface dielectric layer comprises silicon nitride, and the insulation layer comprises aluminum oxide.

12. The method of claim 11, wherein the insulation layer has a thickness of about 10 nanometers.

13. The method of claim 1, further comprising:
before forming the gate contact, forming an insulation layer on the epiwafer, wherein the insulation layer covers the surface dielectric layer and the first region of the surface of the epiwafer;
wherein forming the gate contact comprises forming the gate contact on the insulation layer.

14. The method of claim 13, wherein the epiwafer comprises an epitaxial structure including a channel layer and a barrier layer that are configured to form a two dimensional electron gas (2DEG) at an interface between the channel layer and the barrier layer, and wherein a material composition and thickness of the insulation layer are selected to deplete the 2DEG of carriers under zero bias conditions.

15. A semiconductor transistor device comprising:
a substrate and a semiconductor epitaxial structure on the substrate;
a source contact on a surface of the semiconductor epitaxial structure;
a drain contact on the surface of the semiconductor epitaxial structure; and
a gate contact on the surface of the semiconductor epitaxial structure between the source contact and the drain contact;
wherein the gate contact has a gate length less than about 0.1 microns.

16. The semiconductor transistor device of claim 15, wherein the gate length is between about 0.05 microns and 0.08 microns.

17. The semiconductor transistor device of claim 16, wherein the gate length is about 0.07 microns.

18. The semiconductor transistor device of claim 15, wherein the semiconductor transistor device is configured to operate at frequencies greater than 1 GHz.

19. The semiconductor transistor device of claim 15, wherein the gate contact has a gamma-gate arrangement.

20. The semiconductor transistor device of claim 15, further comprising:
an insulation layer on the surface of the semiconductor epitaxial structure between the gate contact and the semiconductor epitaxial structure.

21. The semiconductor transistor device of claim 20, wherein the epitaxial structure comprises a channel layer and a barrier layer that are configured to form a two dimensional electron gas (2DEG) at an interface between the channel layer and the barrier layer, and wherein a material composition and thickness of the insulation layer are selected to deplete the 2DEG of carriers under zero bias conditions.

22. The semiconductor transistor device of claim 20, wherein the insulation layer comprises aluminum oxide and has a thickness of at least about 10 nanometers.

23. A monolithic microwave integrated circuit (MMIC) comprising the semiconductor transistor device of claim 15.

24. A method of forming a transistor device, comprising:
providing an epiwafer comprising a substrate and one or more epitaxial layers;
forming first source and drain contacts on a surface of the epiwafer;
forming second source and drain contacts on the surface of the epiwafer;
forming a surface dielectric layer on the surface of the epiwafer;
forming a first opening in the surface dielectric layer between the first source and drain contacts, the first opening having a first width and exposing a first region of the surface of the epiwafer;
forming a second opening in the surface dielectric layer between the second source and drain contacts, the second opening having a second width and exposing a second region of the surface of the epiwafer;
forming a first gate contact in the first opening, the first gate contact having a first gate width that is less than the first width;
forming an insulation layer on the surface of the epiwafer, wherein the insulation layer covers the surface dielectric layer, the first and second source and drain contacts, the first gate contact, and the second opening; and
forming a second gate contact in the second opening, the second gate contact having a second gate width that is less than the second width.

25. The method of claim 24, wherein forming the first opening and the second opening comprises:
forming a mask layer on the epiwafer, the mask layer having a third opening that is offset from the first opening, wherein the third opening exposes a portion of the first region of the surface of the epiwafer and a portion of the surface dielectric layer adjacent the first region of the surface of the epiwafer and having a fourth opening that is offset from the second opening, wherein the fourth opening exposes a portion of the second region of the surface of the epiwafer and a portion of the surface dielectric layer adjacent the second region of the surface of the epiwafer.

26. The method of claim 24, wherein the insulation layer has a different material composition than the surface dielectric layer.

27. The method of claim 26, wherein the surface dielectric layer comprises silicon nitride, and the insulation layer comprises aluminum oxide.

28. The method of claim 26, wherein the epiwafer comprises an epitaxial structure including a channel layer and a barrier layer that are configured to form a two dimensional electron gas (2DEG) at an interface between the channel layer and the barrier layer, and wherein a material composition and thickness of the insulation layer are selected to deplete the 2DEG of carriers under zero bias conditions in an area beneath the second gate contact.

29. An integrated electronic device, comprising:
a semiconductor die comprising a substrate and an epitaxial structure on the substrate;
